(19) United States
(12) Patent Application Publication
(10) Pub. No.: US 2026/0277122 A1
(43) Pub. Date: Sep. 17, 2026

(54) ACTUATOR, STAGE APPARATUS, LITHOGRAPHY APPARATUS AND ARTICLE MANUFACTURING METHOD

(71) Applicant: CANON KABUSHIKI KAISHA, Tokyo (JP)

(72) Inventor: NORIHIRO SAKURAKAWA, Tochigi (JP)

(21) Appl. No.: 19/563,026

(22) Filed: Mar. 11, 2026

(30) Foreign Application Priority Data
Mar. 14, 2025 (JP) 2025-041570

(51) Int. Cl. G03F 7/00; H02K 41/035

(52) U.S. Cl. CPC G03F 7/70758; G03F 7/70716; G03F 7/70808; H02K 41/035

(57) ABSTRACT

An actuator comprising a stator, and a mover configured to move along the stator, wherein the mover includes a housing, a yoke, a magnet adhered to one surface of the yoke via an adhesion layer, and a plurality of fastening members configured to fasten the housing and the yoke, and on an attachment surface of the housing, to which a structure of a driving target of the actuator is attached, the plurality of fastening members are arranged in a non-corner region other than corner regions including corner portions of a sectional region of a cross section of the yoke parallel to the attachment surface.

### BACKGROUND

### FIELD OF THE TECHNOLOGY

The present disclosure relates to an actuator, a stage apparatus, a lithography apparatus and an article manufacturing method.

### DESCRIPTION OF THE RELATED ART

In an exposure apparatus used to manufacture a device such as a semiconductor element, a machine tool, a driving apparatus that needs precise positioning for a railway or the like, or a structure (building) that receives an excessive load, bolts, rivets, adhesives, and the like are used to fix components. For example, Japanese Patent Laid-Open No. 2023-171947 discloses a technique of, concerning a structure, fixing (fastening) components using bolts and adhesives.

In recent years, a lithography apparatus represented by an exposure apparatus is required to further improve productivity, and to meet this requirement, for example, driving of a driving apparatus for driving a substrate stage holding a substrate is required to be sped up. To implement high-speed driving of the driving apparatus, a high thrust needs to be generated by an electromagnetic actuator used in the driving apparatus, but the mover (structure) of the electromagnetic actuator receives a high load (stress) according to the generated thrust. For this reason, the load acting on the mover may propagate to bolts or adhesives fixing components and exceed the allowable stress of the bolts or adhesives, resulting in breakage of the bolts or adhesives. To prevent the load acting on the mover from exceeding the allowable stress of the bolts or adhesives, the strength of the mover (structure) may be increased. However, this may increase the mass of the mover, and it may be impossible to cause the electromagnetic actuator to generate the necessary thrust.

### SUMMARY

The present disclosure provides a new technique concerning an actuator advantageous in implementing speedup of driving.

According to one aspect of the present disclosure, there is provided an actuator including a stator, and a mover configured to move along the stator, wherein the mover includes a housing, a yoke, a magnet adhered to one surface of the yoke via an adhesion layer, and a plurality of fastening members configured to fasten the housing and the yoke, and on an attachment surface of the housing, to which a structure of a driving target of the actuator is attached, the plurality of fastening members are arranged in a non-corner region other than corner regions including corner portions of a sectional region of a cross section of the yoke parallel to the attachment surface.

Further aspects of the present disclosure will become apparent from the following description of exemplary embodiments with reference to the attached drawings.

### BRIEF DESCRIPTION OF THE DRAWINGS

FIG. 1A and FIG. 1B are schematic views illustrating configurations of an actuator according to an aspect of the present disclosure.

FIGS. 2A and 2B are views illustrating the state of the actuator before deformation of a housing and the state of the actuator after deformation of the housing, respectively.

FIG. 3 is a view illustrating an example of the positions of fastening members arranged on the attachment surface of the housing.

FIG. 4 is a view illustrating an example of the positions of first fastening members and second fastening members arranged on the attachment surface of the housing.

FIG. 5 is a view illustrating an example of the configurations of a first bolt and a second bolt, which are a plurality of fastening members.

FIG. 6 is a view for specifically explaining an example of the positions of fastening members arranged on the attachment surface of the housing.

FIG. 7 is a view for specifically explaining an example of the positions of fastening members arranged on the attachment surface of the housing.

FIG. 8 is a view for specifically explaining another example of the positions of fastening members arranged on the attachment surface of the housing.

FIG. 9 is a view for specifically explaining still another example of the positions of fastening members arranged on the attachment surface of the housing.

FIG. 10 is a view for specifically explaining yet another example of the positions of fastening members arranged on the attachment surface of the housing.

FIG. 11 is a view for specifically explaining still other example of the positions of fastening members arranged on the attachment surface of the housing.

FIG. 12 is a view illustrating the positions (fastening positions) of fastening members arranged on the upper surface of the housing.

FIGS. 13A and 13B are views for explaining an effect according to the embodiment.

FIG. 14 is a schematic view illustrating configurations of a stage apparatus according to an aspect of the present disclosure.

FIG. 15 is a schematic view illustrating configurations of an exposure apparatus according to an aspect of the present disclosure.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

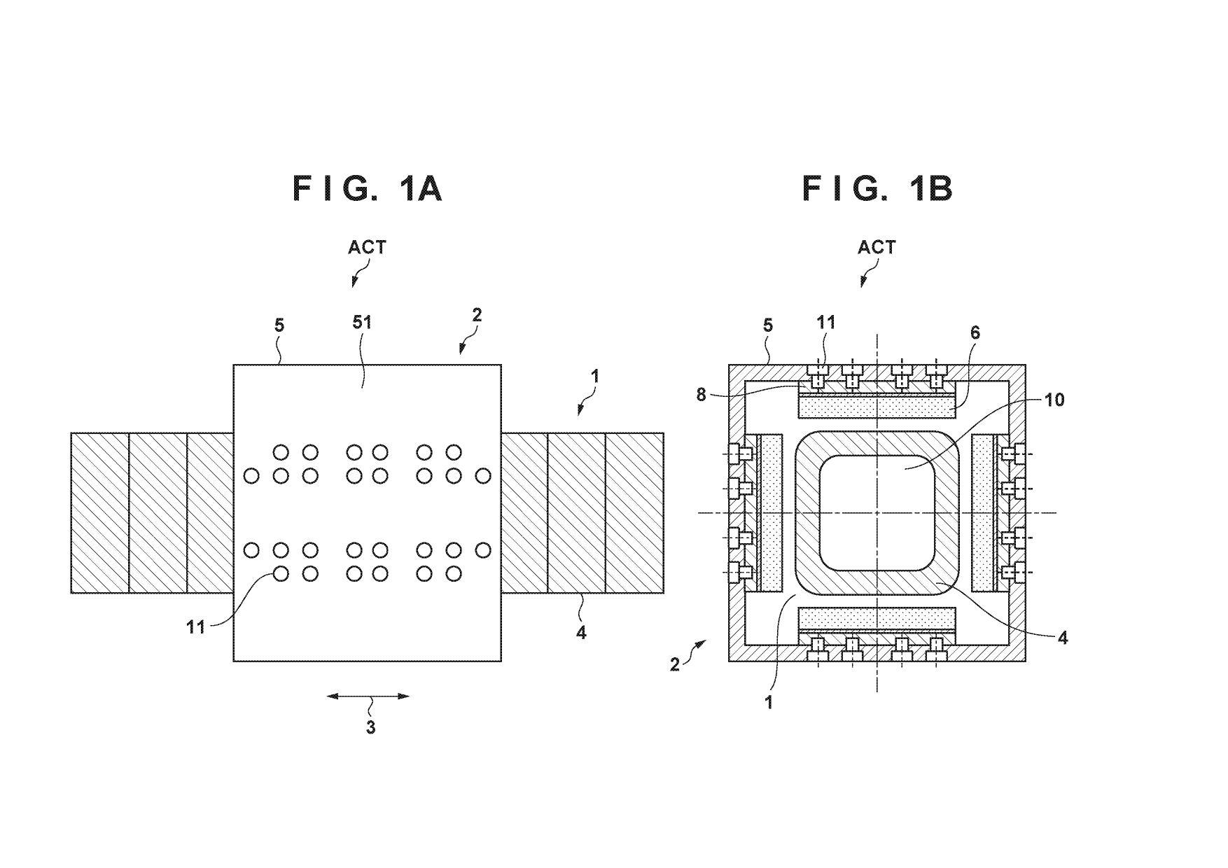

FIGS. 1A and 1B are schematic views illustrating configurations of an actuator ACT according to an aspect of the present disclosure. FIG. 1A is a side view of the actuator ACT, and FIG. 1B is a sectional view of the actuator ACT. In this embodiment, the actuator ACT is embodied as an electromagnetic actuator, and includes a stator 1, and a mover 2 that moves along (the longitudinal direction of) the stator 1. Note that in this embodiment, the stator 1 and the mover 2 each have a rectangular sectional shape, but the sectional shapes of the stator 1 and the mover 2 are not limited and may be circular or elliptical. Also, in this embodiment, the stator 1 includes coils, and the mover 2 includes magnets. However, the stator 1 may include magnets, and the mover 2 may include coils. As described above, the sectional shapes and configurations of the stator 1 and the mover 2 can arbitrarily be changed.

The stator 1 has a columnar shape extending along a first direction 3, and includes a support member 10 arranged at the axis center and a plurality of coils 4 arranged on the outer side surfaces of the support member. The support member 10 can function as a base for supporting the coils 4. The support member 10 internally includes a cooling path configured to cool the coils 4. The cooling path has, for example, a circular sectional shape and is used to cool the coils 4 by forming a refrigerant circulation path with an external tube connected. To improve the cooling efficiency for the coils 4 by the refrigerant flowing through the cooling path, the support member 10 is preferably made of a material with a high thermal conductivity.

The mover 2 has a hollow shape surrounding the outer side surfaces of the stator 1 and extending in the first direction 3, and includes a housing 5, yokes 8, magnets 6, and fastening members 11. A plurality of magnets 6, that is, two pairs of facing magnets are arranged on the inner side surfaces of the housing 5 (mover 2). The plurality of magnets 6 include magnets magnetized in the axial direction and magnets magnetized in the circumferential direction, and the array thereof is decided such that an alternating magnetic field is generated on the inner side surfaces of the housing 5. In this embodiment, the plurality of magnets 6 are arranged in a Halbach array that generates a one-cycle substantially sine wave magnetic field.

Each magnet 6 is adhered to (held on) (a part or whole of) one surface of a corresponding yoke 8 via an adhesion layer 7 made of an adhesive. The fastening members 11 fasten (fix) the yoke 8 and the housing 5 on a surface opposite to the surface of the yoke 8 with the magnet 6 adhered. The fastening members 11 typically include bolts and rivets. To fasten the yoke 8 and the housing 5, an adhesive or the like may be used in addition to the fastening members 11.

In the actuator ACT, the plurality of coils 4 are formed by a plurality of phases and, in this embodiment, two phases including an A phase and a B phase. The driving method of the actuator ACT is a general sine wave driving, and control is performed such that a current and a magnetic flux are orthogonal. Note that to reduce heat generation of the coils 4, it is preferable to energize only the coils 4 facing the magnets 6 in the plurality of coils 4 and perform switching of the coils 4 to be energized in addition to the general sine wave driving.

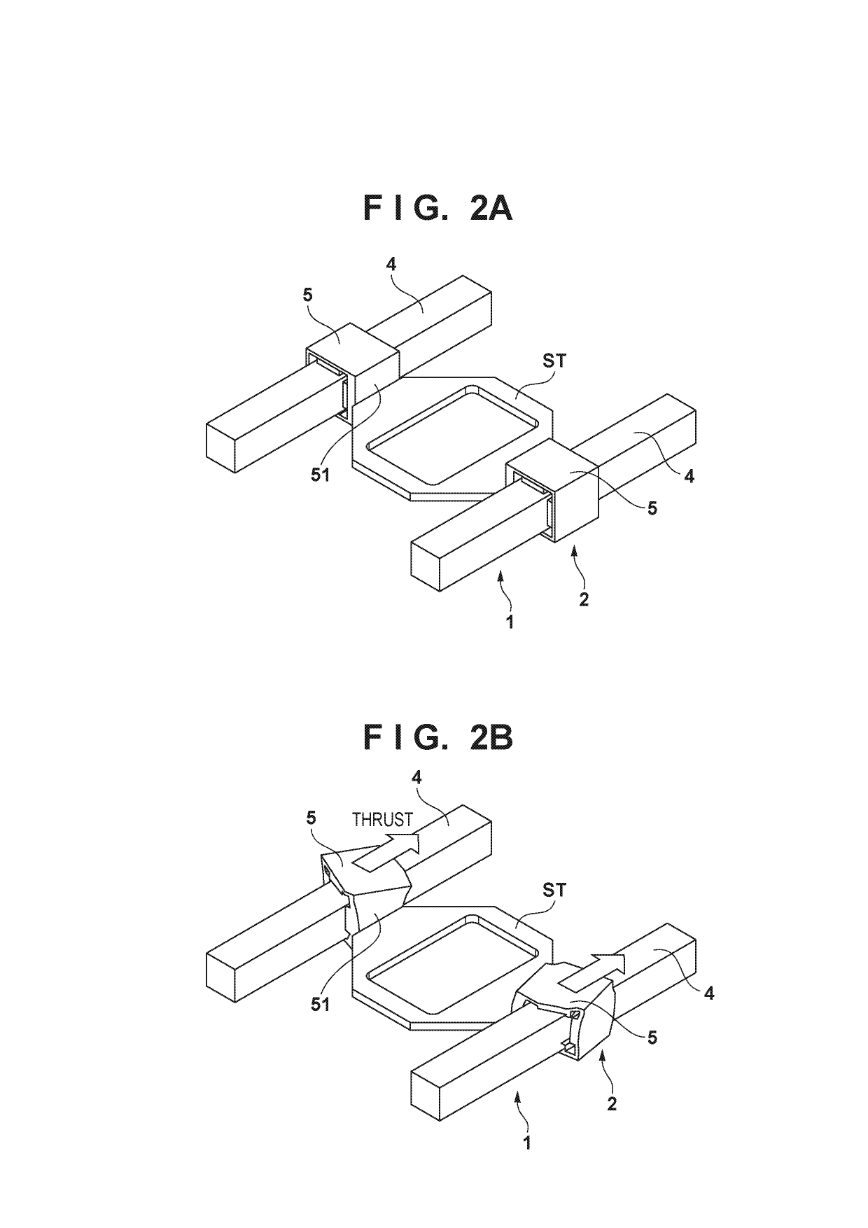

In the actuator ACT, to use the magnetic field generated by the coils 4 efficiently as a driving force (thrust), the coils 4 and the magnets 6 are preferably as close as possible. By a Lorentz force generated by energizing the coils 4, the mover 2 receives a thrust, and the thrust propagates to the adhesion layers 7, the yokes 8, and the housing 5 through the magnets 6. Upon receiving the thrust, the housing 5 (mover 2) is deformed by an inertial force generated between an attachment surface 51 of the housing 5 to which a structure as the driving target of the actuator ACT is attached and the structure of the driving target, and stress is generated. FIGS. 2A and 2B are views illustrating the state of the actuator ACT before deformation of the housing 5 and the state of the actuator ACT after deformation of the housing 5, respectively. Referring to FIGS. 2A and 2B, the deformation of the housing 5 is largest on the attachment surface 51 to which a structure ST is attached. Also, in the housing 5, a corner portion on the far side in the direction (the direction of an arrow) in which the thrust is generated deforms to the inner side (the side of the structure ST), and a corner portion on the near side in the direction in which the thrust is generated deforms to the outer side (the side of the coils 4). The deformation of the housing 5 propagates from the housing 5 to the yoke 8, the adhesion layer 7, and the magnet 6, and stress is generated for each of these. If the stress exceeds the allowable stress of the adhesion layer 7, the adhesion layer 7 breaks, and the magnet 6 may fall.

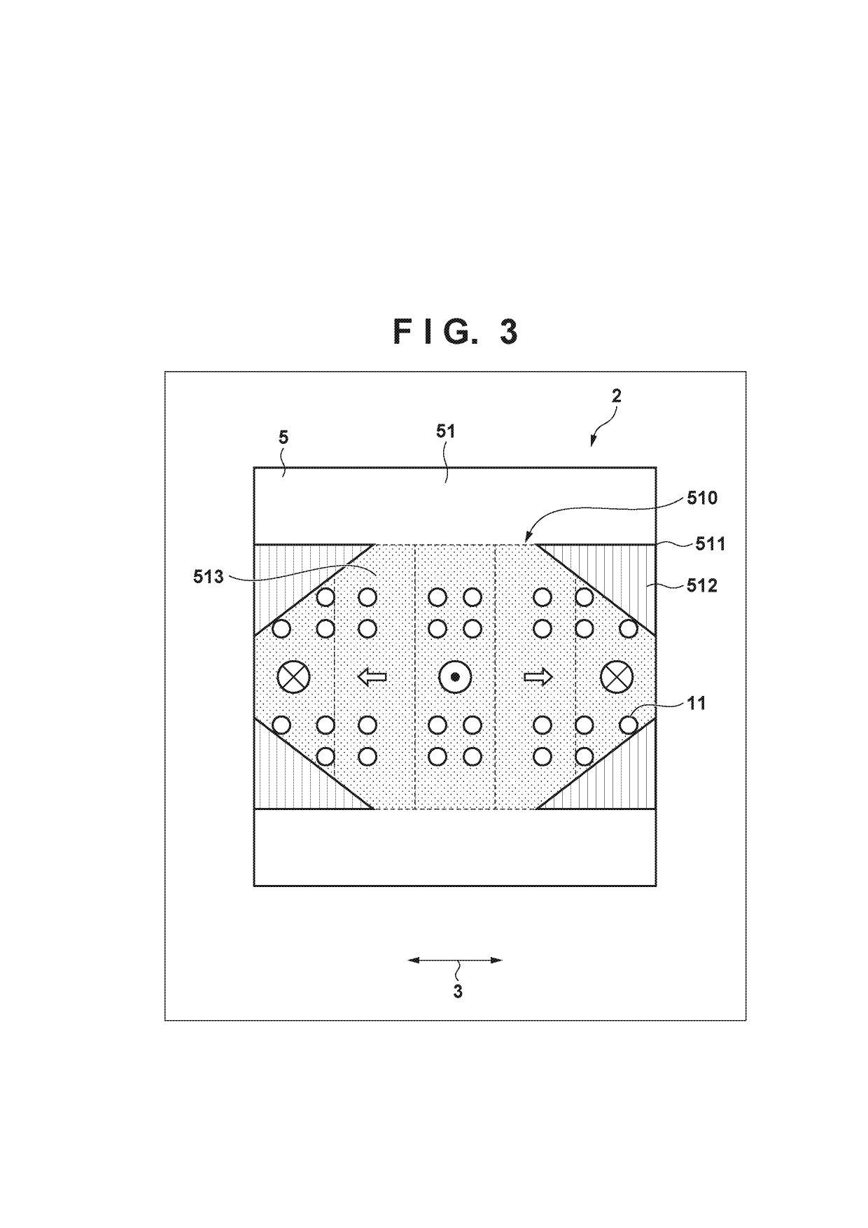

In this embodiment, on the attachment surface 51 of the housing 5, (the fastening positions of) the fastening members 11 that fasten (fix) the housing 5 and the yoke 8 are not arranged at the corner portions of the yoke 8. More specifically, as shown in FIG. 3, on the attachment surface 51 of the housing 5, the plurality of fastening members 11 are arranged in a non-corner region 513 other than corner regions 512 including corner portions 511 of a projection region 510 formed by projecting the yoke 8 to the attachment surface 51. In this embodiment, since the yoke 8 has a rectangular shape, the projection region 510 projected to the attachment surface 51 of the housing 5 also has a rectangular shape. Note that the projection region 510 of the yoke 8 on the attachment surface 51 corresponds to the sectional region of a cross section of the yoke 8 parallel to the attachment surface 51. FIG. 3 is a view illustrating an example of the positions (fastening positions) of the fastening members 11 arranged on the attachment surface 51 of the housing 5.

As described above, by the inertial force generated between the attachment surface 51 of the housing 5 and the structure ST of the driving target, particularly large bending stress (shearing stress) is generated in (the corner regions including) the corner portions of the yoke 8 (housing 5). Hence, in this embodiment, the fastening members 11 are arranged not in the corner regions including the corner portions of the yoke 8, which are portions of large bending stress, that is, the corner regions 512 on the attachment surface 51 of the housing 5 but in the non-corner region 513. Since this reduces the stress propagating from the housing 5 to the yoke 8, stress propagating from the yoke 8 to the adhesion layer 7 is also reduced, and it is possible to suppress breakage of the adhesion layer 7 and prevent the magnet 6 from falling. Note that in this embodiment, the corner regions 512 are regions where the fastening members 11 are not arranged, and the space between the housing 5 and the yoke 8 corresponding to each corner region 512 is kept void to avoid the deformation of the housing 5 or filled with a material of low stiffness relative to the housing 5 and the yoke 8.

Also, in this embodiment, since the fastening members 11 are arranged in the non-corner region 513 that is a portion of relatively small bending stress, it is possible to suppress breakage of the fastening members 11 even if the bending stress propagates from the yoke 8 to the fastening members 11 via the adhesion layer 7. Note that to further suppress breakage of the fastening members 11, the stiffness (axial stiffness) of the plurality of fastening members 11 is preferably made lower than the stiffness (bending stiffness) of the yoke 8 such that the fastening members 11 deform following the bending stress (deformation) of the yoke 8 (housing 5).

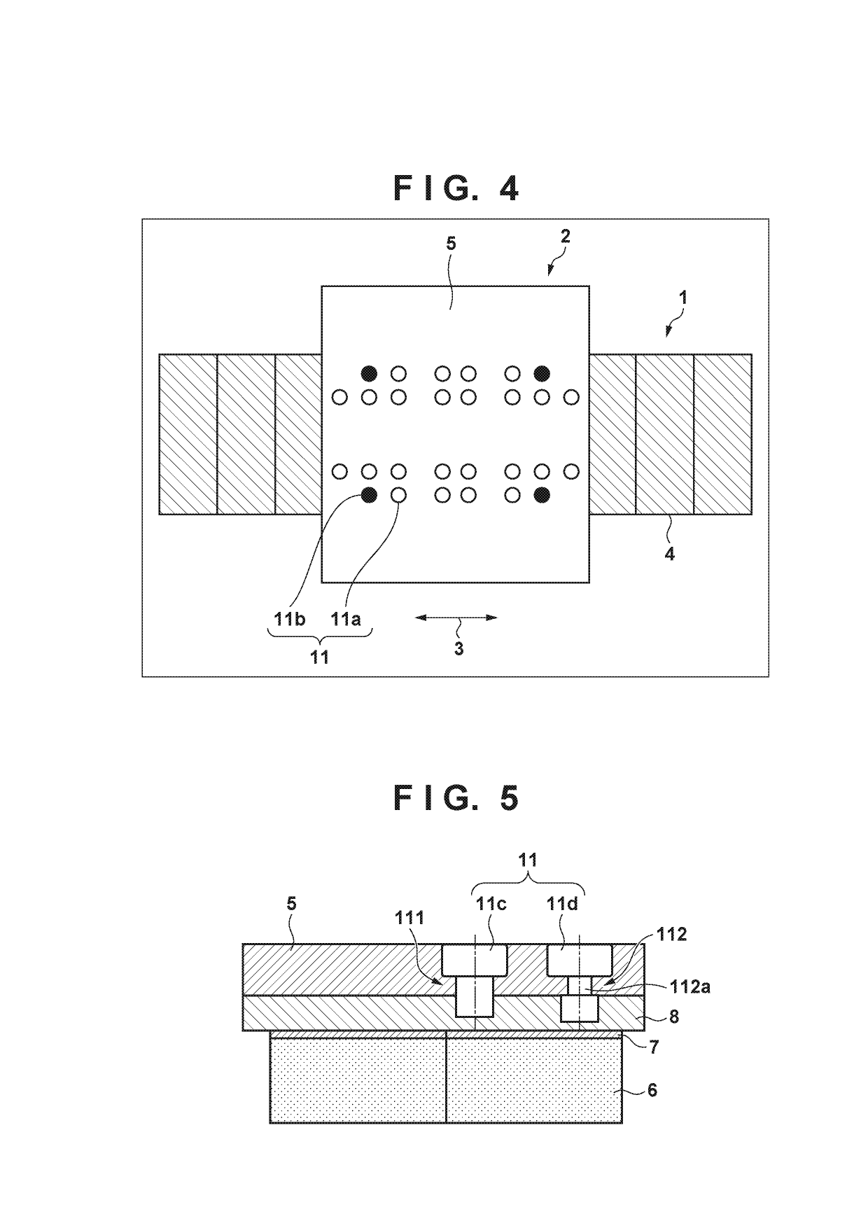

In addition, all the plurality of fastening members 11 need not have the same stiffness (Young's modulus) and, for example, first fastening members 11a having a high stiffness (first stiffness) and second fastening members 11b having a low stiffness (second stiffness lower than the first stiffness) may be included. The first fastening member 11a and the second fastening member 11b are made of different materials. More specifically, the first fastening member 11a is made of carbon steel or stainless steel, and the second fastening member 11b is made of titanium or aluminum. If the fastening members 11 include the first fastening members 11a and the second fastening members 11b having different stiffnesses, the second fastening members 11b are preferably arranged in portions of the yoke 8 with large bending stress, as shown in FIG. 4. Hence, in this embodiment, the second fastening members 11b are arranged at positions close to the corner regions 512 on the attachment surface 51 of the housing 5, as compared to the first fastening members 11a. This reduces tensile stress acting on the fastening members 11 when the bending stress (shearing stress) propagates from the housing 5 to the yoke 8. In other words, the second fastening members 11b deform (stretch) more, and the stress propagating between the housing 5 and the yoke 8 can be reduced. Note that the positions and the number of second fastening members 11b shown in FIG. 4 are merely examples and are not limited to these.

Also, if the plurality of fastening members 11 are bolts, the plurality of fastening members 11 may include first bolts 11c each having an underhead portion 111 of a first diameter, and second bolts 11d each having an underhead portion 112 including a portion 112a of a second diameter smaller than the first diameter, as shown in FIG. 5. A part (second diameter) of the screw diameter of the second bolt 11d is thus made smaller than the screw diameter (first diameter) of the first bolt 11c. Thus, even if the first bolt 11c and the second bolt 11d are made of the same material, it is possible to make the stiffness of the second bolt 11d lower than the stiffness of the first bolt 11c and facilitate deformation (stretching) of the second bolt 11d as compared to the first bolt 11c. Hence, when the second bolts 11d are arranged at positions close to the corner regions 512 on the attachment surface 51 of the housing 5, as compared to the first bolts 11c, the stress propagating between the housing 5 and the yoke 8 can be reduced. FIG. 5 is a view illustrating an example of the configurations of the first bolt 11c and the second bolt 11d, which are the plurality of fastening members 11.

Detailed arrangements of the plurality of fastening members 11 on the attachment surface 51 of the housing 5 will be described below.

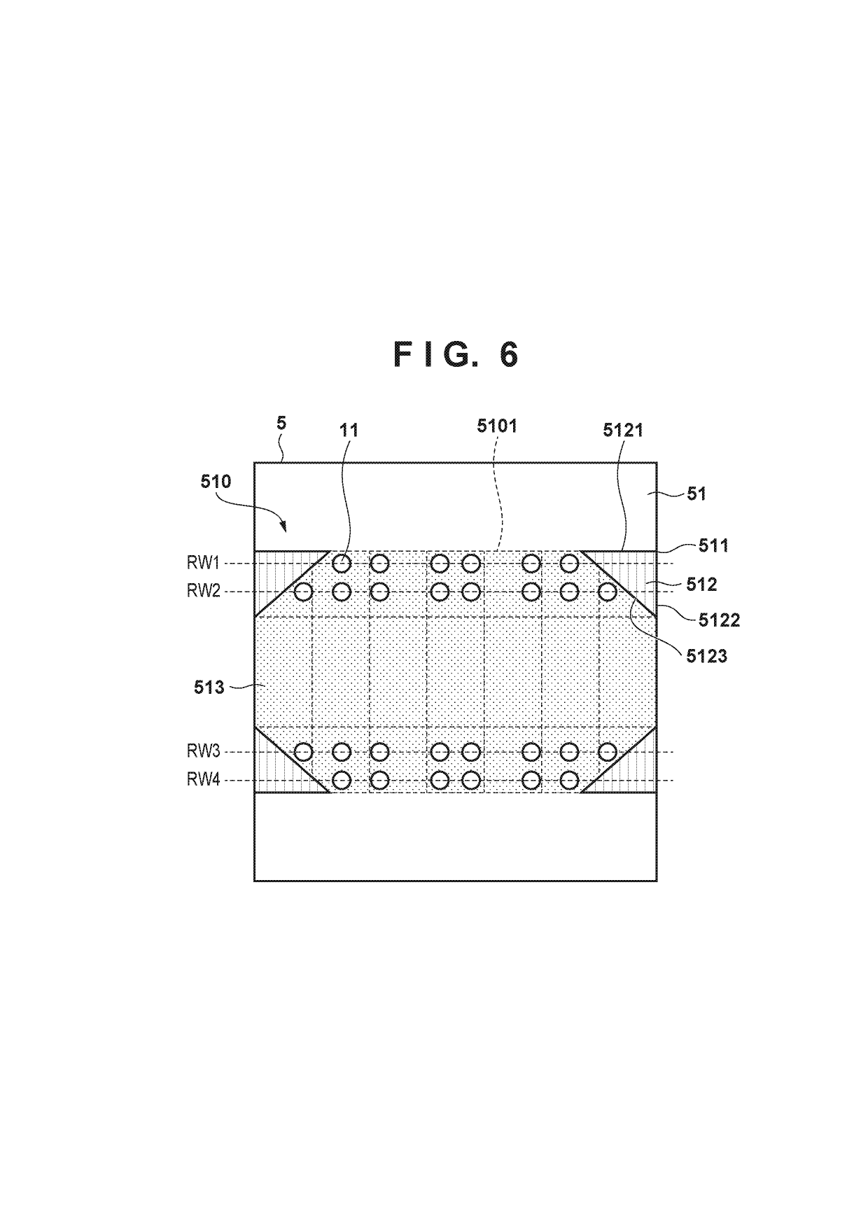

FIG. 6 is a view for specifically explaining an example of the positions (fastening positions) of the fastening members 11 arranged on the attachment surface 51 of the housing 5. Referring to FIG. 6, each corner region 512 is defined by a triangular region having one vertex at the corner portion 511 of the projection region 510 of the yoke 8 projected to the attachment surface 51 of the housing 5. Two sides that define the one vertex (corner portion 511) of the triangle are a first side 5121 (one side) and a second side 5122 (the other side). The first side 5121 has a length not more than 10% the length of a long side 5101 of the projection region 510, and the second side 5122 has a length not more than 10% the length of a short side 5102 of the projection region 510. On the other hand, the non-corner region 513 is defined by an octagonal region including an opposite side 5123 of the corner portion 511 (one vertex of the triangle) of the corner region 512.

In this case, the plurality of fastening members 11 are arranged along a plurality of rows RW1, RW2, RW3, and RW4 in the non-corner region 513, as shown in FIG. 6. The number of fastening members 11 arranged on each of the outermost rows RW1 and RW4 in the plurality of rows RW1 to RW4 is smaller than the number of fastening members 11 arranged on each of the rows RW2 and RW3 inside the outermost rows RW1 and RW4. In this embodiment, the number of fastening members 11 arranged on each of the outermost rows RW1 and RW4 is 6, and the number of fastening members 11 arranged on each of the rows RW2 and RW3 inside the outermost rows RW1 and RW4 is 8.

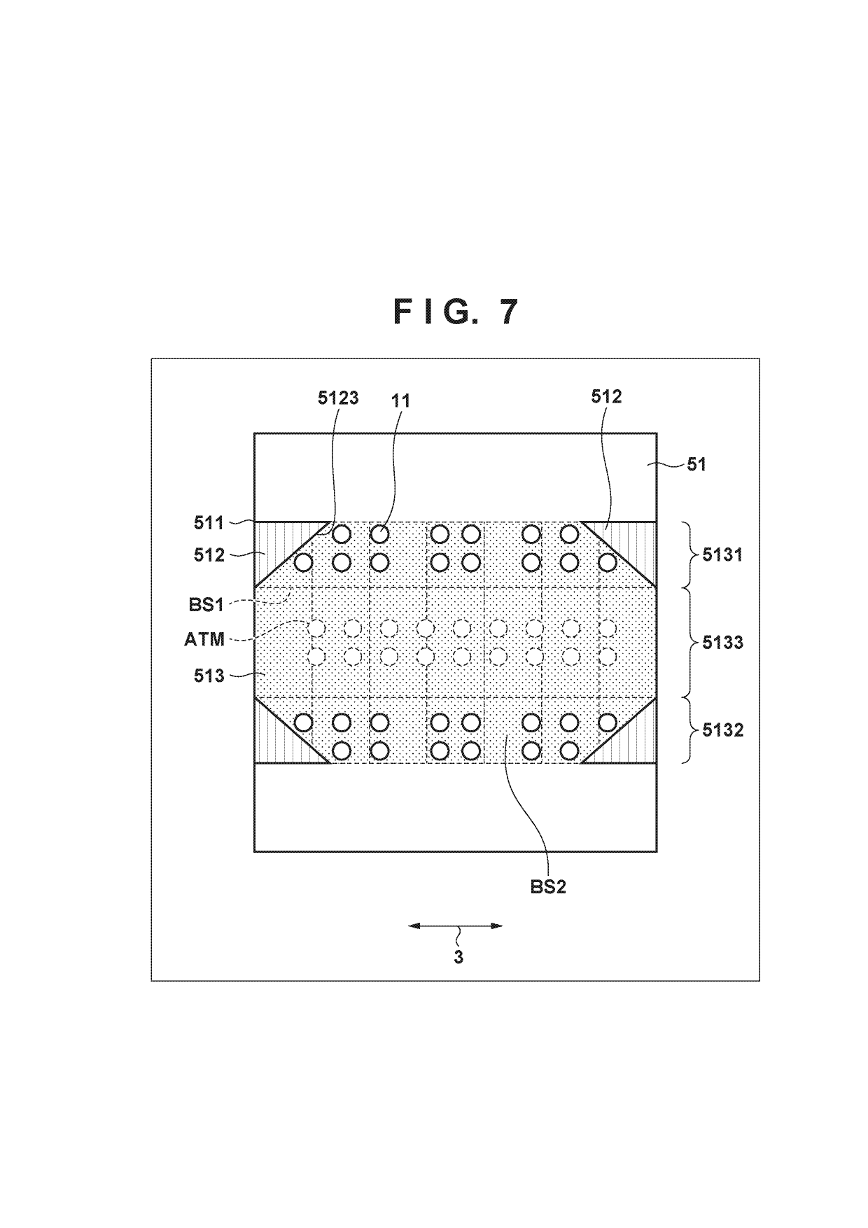

As shown in FIG. 7, the non-corner region 513 includes three regions defined along the first direction 3 (the moving direction of the mover 2), that is, an upper region 5131, a lower region 5132, and an intermediate region 5133 between the upper region 5131 and the lower region 5132. The fastening members 11 are arranged in the upper region 5131 and the lower region 5132. On the other hand, in the intermediate region 5133, the fastening members 11 are not arranged, and the structure ST of the driving target is attached, that is, attachment members ATM used to attach the structure ST to the attachment surface 51 of the housing 5 are arranged. Note that each of the upper region 5131 and the lower region 5132 is defined by a trapezoidal region having the opposite side 5123 of the corner portion 511 (one vertex of the triangle) of the corner region 512 as a leg. The intermediate region 5133 is defined by a rectangular region having, as opposite sides, a base BS1 of the trapezoid defining the upper region 5131 on the side of the intermediate region 5133 and a base BS2 of the trapezoid defining the lower region 5132 on the side of the intermediate region 5133.

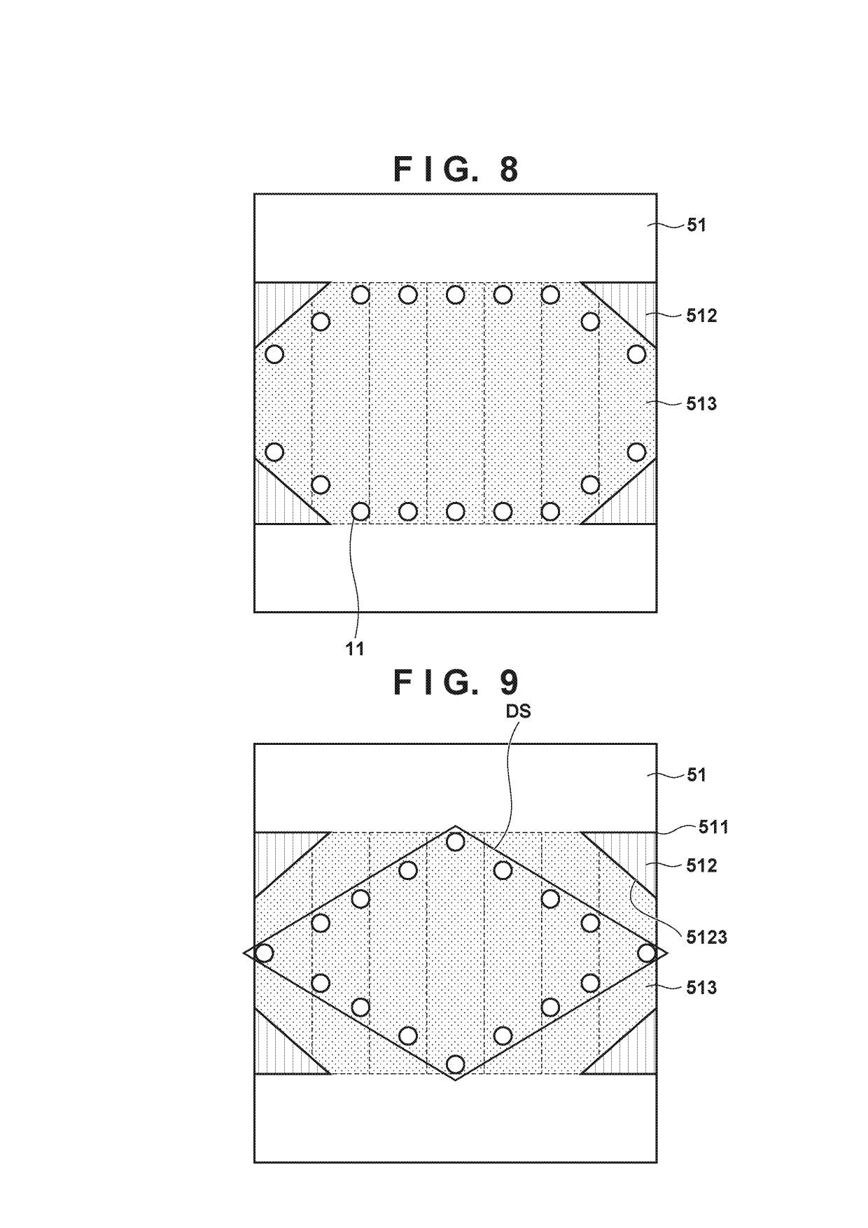

FIG. 8 is a view for specifically explaining another example of the positions (fastening positions) of the fastening members 11 arranged on the attachment surface 51 of the housing 5. As shown in FIG. 8, the plurality of fastening members 11 may be arranged along (the sides of) the octagon defining the non-corner region 513.

FIG. 9 is a view for specifically explaining still another example of the positions (fastening positions) of the fastening members 11 arranged on the attachment surface 51 of the housing 5. As shown in FIG. 9, the plurality of fastening members 11 may be arranged along (the sides of) a rhombus DS inscribed with four sides except the opposite side 5123 of each corner portion 511 (one vertex of the triangle) of the corner region 512 among the eight sides that define the octagon defining the non-corner region 513.

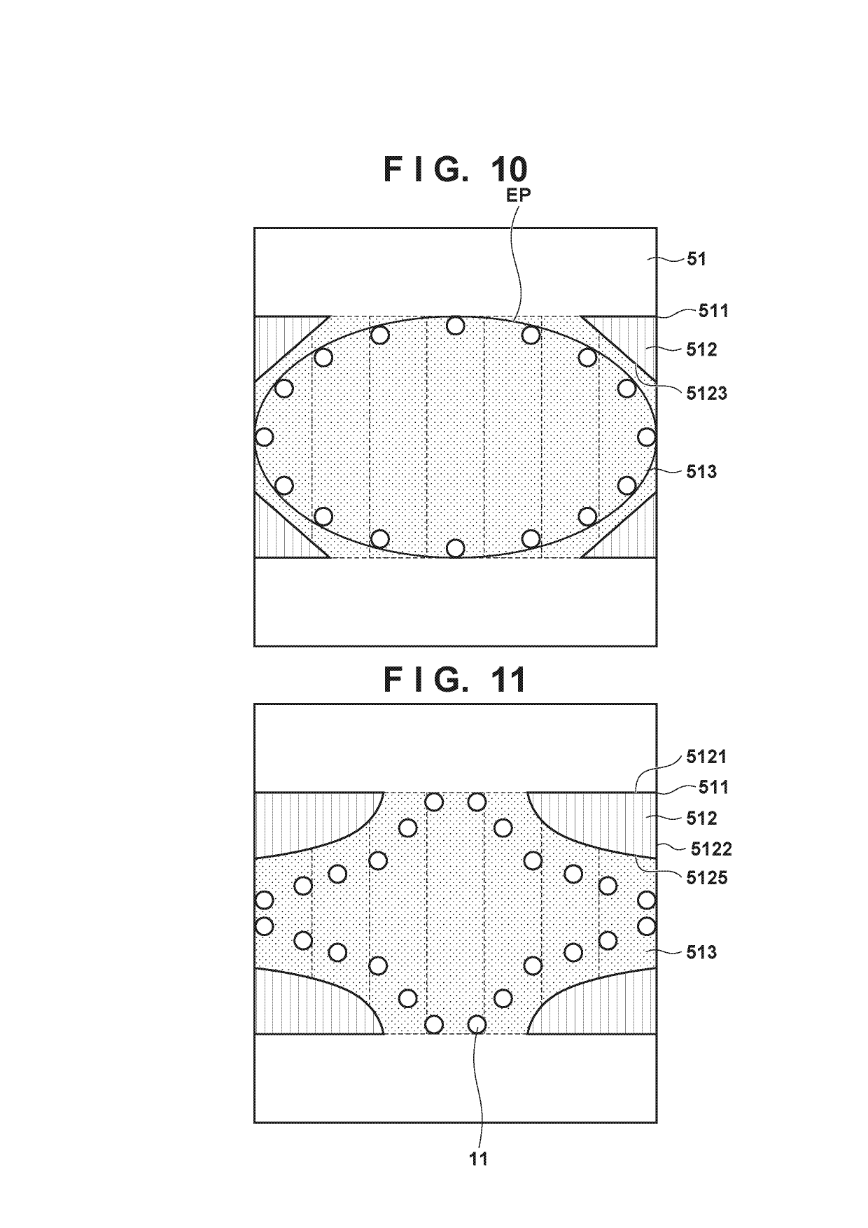

FIG. 10 is a view for specifically explaining yet another example of the positions (fastening positions) of the fastening members 11 arranged on the attachment surface 51 of the housing 5. As shown in FIG. 10, the plurality of fastening members 11 may be arranged along an ellipse EP inscribed with four sides except the opposite side 5123 of each corner portion 511 (one vertex of the triangle) of the corner region 512 among the eight sides that define the octagon defining the non-corner region 513.

FIG. 11 is a view for specifically explaining still another example of the positions (fastening positions) of the fastening members 11 arranged on the attachment surface 51 of the housing 5. Referring to FIG. 11, the corner region 512 is defined by a region of a figure different from a triangular region. The corner region 512 is defined by a region surrounded by the first side 5121 and the second side 5122, which define the corner portion 511 of the projection region 510 of the yoke 8 projected to the attachment surface 51 of the housing 5, and a curve 5125 that connects one point on the first side and one point on the second side. As shown in FIG. 11, the plurality of fastening members 11 may be arranged, in the non-corner region 513, along the curves 5125 defining the corner regions 512.

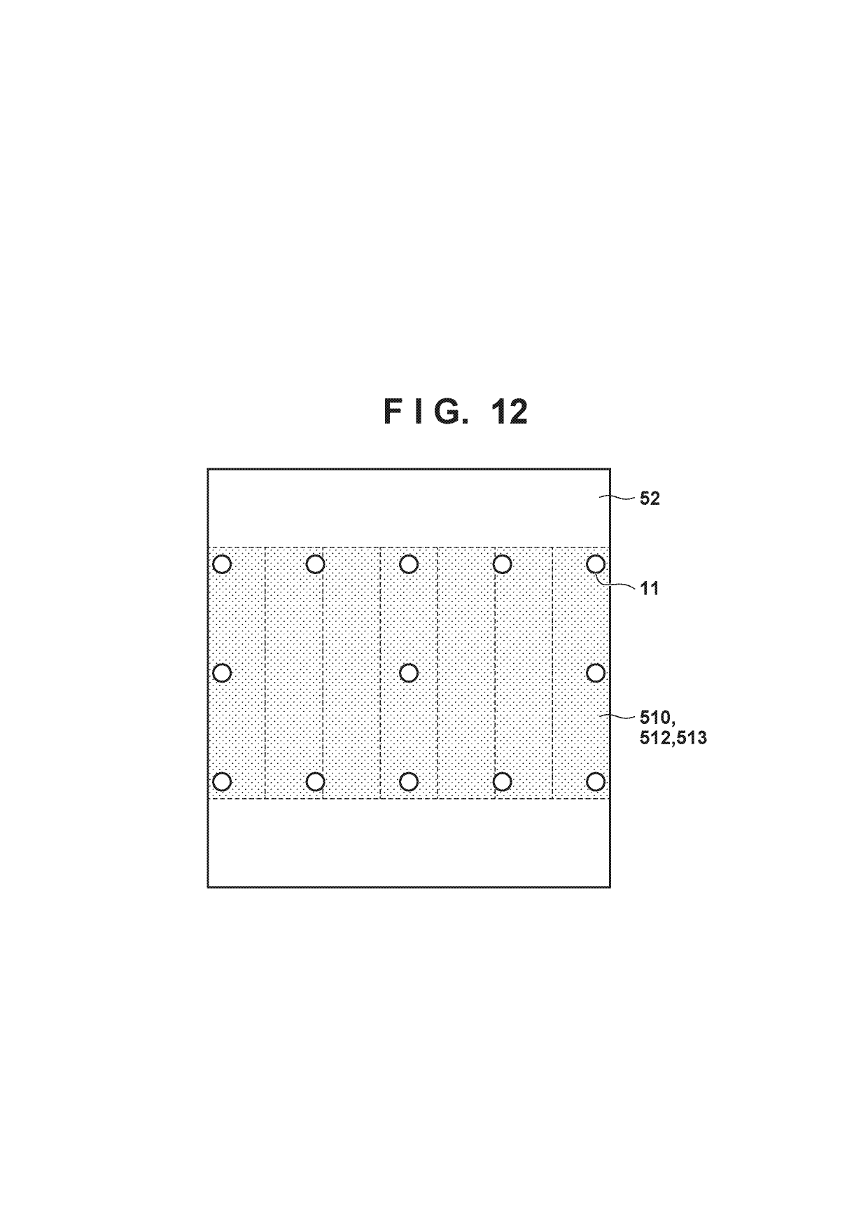

Also, in this embodiment, the arrangement of the plurality of fastening members 11 on the attachment surface 51 of the housing 5 is different from the arrangement of the plurality of fastening members 11 on the other surfaces other than the attachment surface 51 of the housing 5. FIG. 12 is a view illustrating the positions (fastening positions) of the fastening members 11 arranged on an upper surface 52 that is one of the other surfaces other than the attachment surface 51 of the housing 5. Referring to FIG. 12, on the upper surface 52 of the housing 5, the plurality of fastening members 11 are arranged all over the projection region 510 formed by projecting the yoke 8, that is, in both the corner regions 512 and the non-corner region 513. This is because the structure ST is not attached to the other surfaces other than the attachment surface 51 of the housing 5 and, therefore, no local inertial force is applied and deformation at the corner portions of (the projection region 510 of) the yoke 8 is not large. Hence, even if the fastening members 11 are arranged at the corner portions of the yoke 8, stress between the yoke 8 and the magnet 6 does not exceed the allowable stress of the adhesion layer 7, and the adhesion layer 7 never breaks.

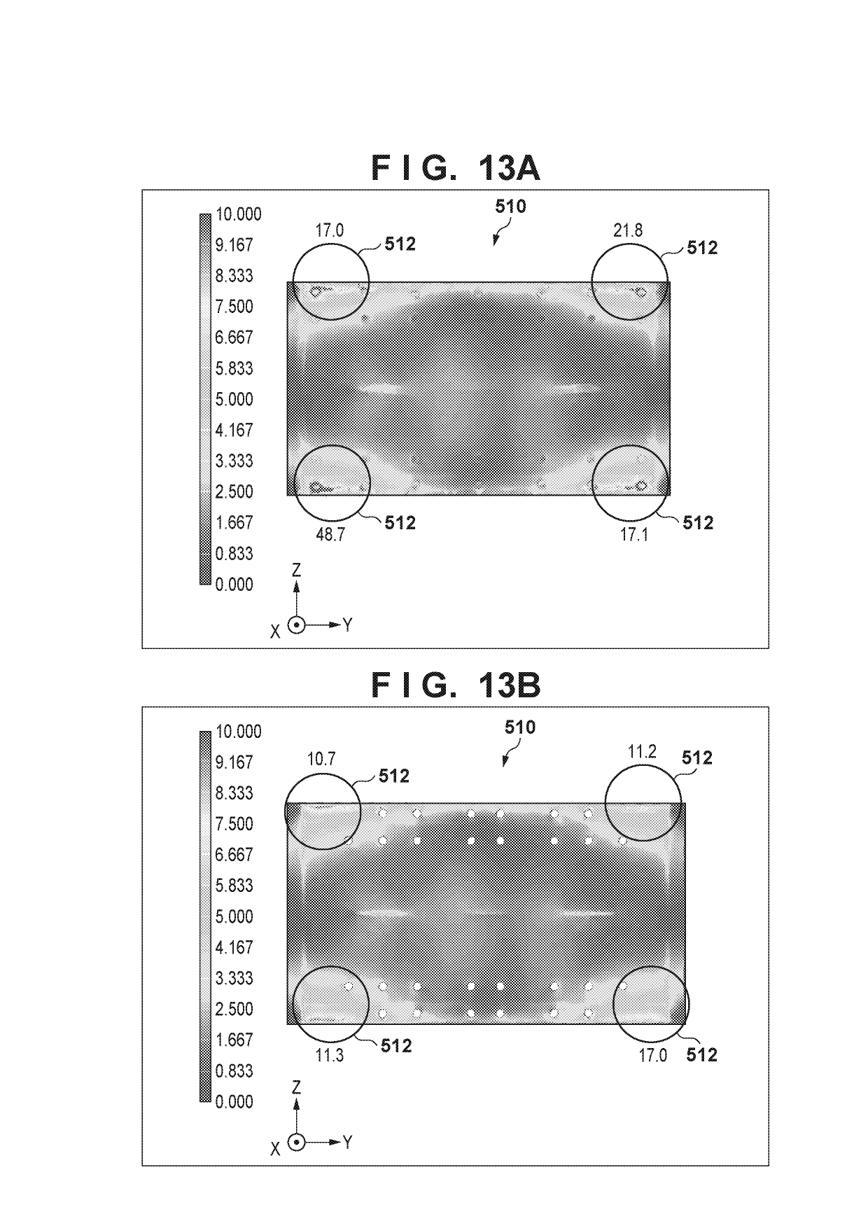

FIGS. 13A and 13B are views for explaining an effect according to this embodiment. FIG. 13A shows the result of simulations of stress generated in the projection region 510 of the yoke 8 in a case where the plurality of fastening members 11 are evenly arranged on the attachment surface 51 of the housing 5 (prior art). FIG. 13B shows the result of simulations of stress generated in the projection region 510 of the yoke 8 in a case where the arrangement of the plurality of fastening members 11 on the attachment surface 51 of the housing 5 is the arrangement shown in FIG. 6 (this embodiment).

The maximum stress value generated in the projection region 510 of the yoke 8 according to this embodiment in the corner regions 512 shown in FIG. 13B can be reduced by about 35% with respect to the maximum stress value generated in the projection region 510 of the yoke 8 according to the prior art in the corner regions 512 shown in FIG. 13A. This is because the fastening members 11 are not arranged in the corner regions including the corner portions of the yoke 8, that is, the corner regions 512 on the attachment surface 51 of the housing 5, which are portions of large bending stress, and stress derived from the deformation of the housing 5 is not propagated.

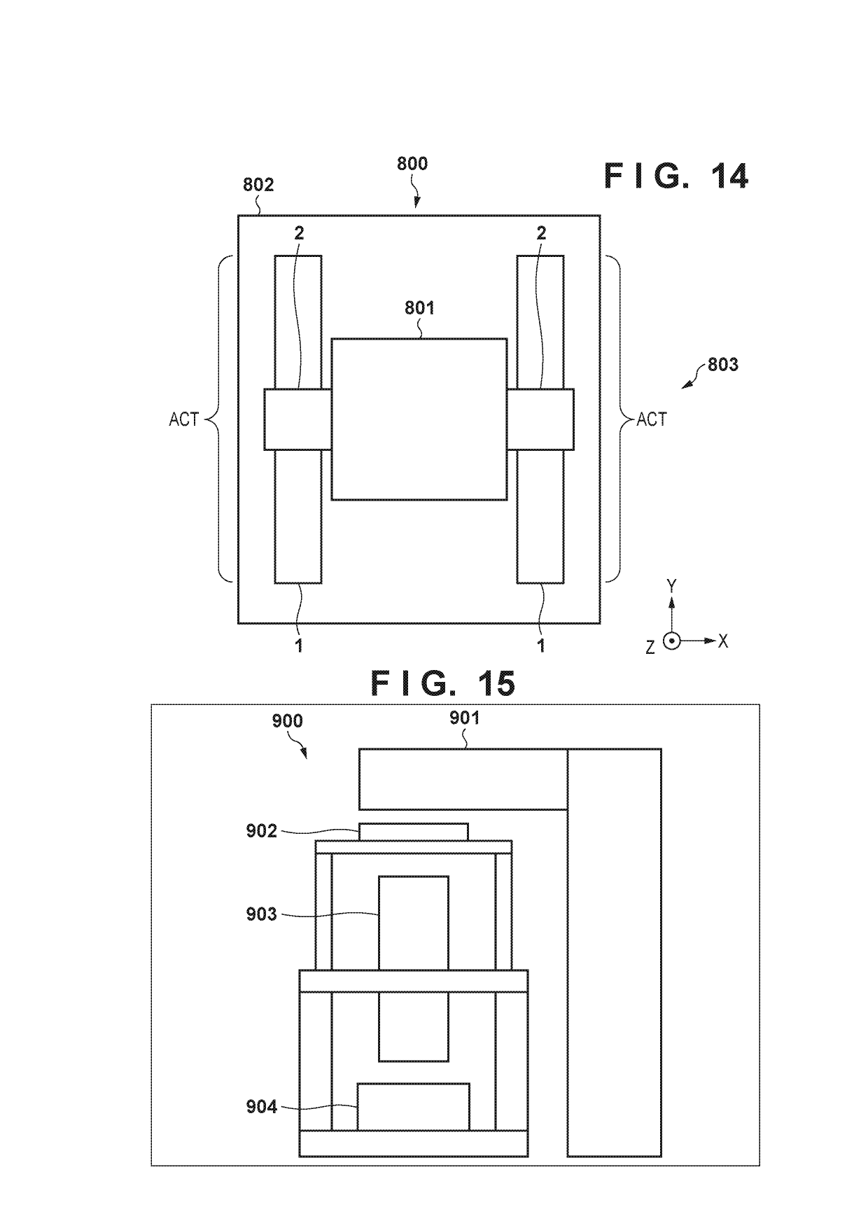

A stage apparatus to which the actuator ACT is applied will be described below with reference to FIG. 14. FIG. 14 is a schematic view illustrating configurations of a stage apparatus 800 according to an aspect of the present disclosure. The stage apparatus 800 includes, on a surface plate 802, a stage 801, and a driving unit 803 including two actuators ACT. In this embodiment, the driving unit 803 is embodied as a linear motor and drives the stage 801. In the stage apparatus 800, a current is supplied to the actuators ACT (the coils 4 are energized), thereby generating a driving force and moving the stage 801 in the Y direction. The actuator ACT applies a thrust to the stage 801 in this way.

Since the above-described actuator ACT is applied to the stage apparatus 800, breakage of the adhesion layer 7 adhering the magnet 6 to the yoke 8 is suppressed, and driving of the stage 801 can be sped up.

An exposure apparatus to which the actuator ACT or the stage apparatus 800 is applied will be described below with reference to FIG. 15. FIG. 15 is a schematic view illustrating configurations of an exposure apparatus 900 according to an aspect of the present disclosure. The exposure apparatus 900 is a lithography apparatus that is employed in a lithography step that is a step of manufacturing a device such as a semiconductor element or a liquid crystal display element, and forms a pattern on a substrate. The exposure apparatus 900 exposes the substrate through an original (a reticle or a mask) and transfers the pattern of the original to the substrate. The exposure apparatus 900 can use a step-and-scan method, a step-and-repeat method, or other exposure methods.

As shown in FIG. 15, the exposure apparatus 900 includes an illumination optical system 901, an original stage 902 that holds an original and moves, a projection optical system 903, and a substrate stage 904 that holds a substrate and moves. The actuator ACT or the stage apparatus 800 is used as the substrate stage 904.

The illumination optical system 901 illuminates the original held on the original stage 902 with light from a light source. The illumination optical system 901 includes a lens, a mirror, an optical integrator, an aperture, and the like. Note that as the light source, for example, a laser such as an ArF excimer laser with a wavelength of about 193 nm, a KrF excimer laser with a wavelength of about 248 nm, an F₂ laser with a wavelength of about 157 nm, or a YAG laser can be used. The number of lasers used as the light source is not limited. If a laser is used as the light source, the illumination optical system 901 preferably includes a shaping optical system that shapes a laser beam (parallel light) into a desired shape or an incoherent optical system that makes a coherent laser beam incoherent. The light source is not limited to a laser, and one or a plurality of lamps such as mercury lamps or xenon lamps may be used.

The projection optical system 903 projects the pattern of the original onto the substrate held on the substrate stage 904. The projection optical system 903 can use an optical system including only a plurality of lens elements, or an optical system (catadioptric optical system) including a plurality of lens elements and at least one concave mirror. The projection optical system 903 can also use an optical system including a plurality of lens elements and one diffractive optical element such as a kinoform, or an all-reflective optical system.

If the exposure apparatus 900 uses the step-and-scan method, the original stage 902 and the substrate stage 904 move in synchronism.

In the exposure apparatus 900, since the actuator ACT or the stage apparatus 800 is applied to the substrate stage 904, driving of the substrate stage 904 can be sped up. Hence, the exposure apparatus 900 can improve productivity (throughput) in the lithography step that is a step of manufacturing a device such as a semiconductor element or a liquid crystal display element.

Note that the lithography apparatus is not limited to an exposure apparatus, and the present disclosure can also be applied to a lithography apparatus such as an imprint apparatus or a drawing apparatus. Here, the imprint apparatus brings an imprint material supplied onto a substrate into contact with a mold, and applies curing energy to the imprint material, thereby forming a pattern of a cured product to which the pattern of the mold is transferred. Also, the drawing apparatus performs drawing on a substrate by a charged particle beam (electron beam) or a laser beam, thereby forming a pattern (latent image pattern) on the substrate.

An article manufacturing method according to the embodiment of the present disclosure is suitable for manufacturing an article, for example, a device (a semiconductor element, a magnetic storage medium, a liquid crystal display element, or the like). The manufacturing method includes a step of exposing, using the exposure apparatus 900, a substrate to which a photoresist is applied (forming a pattern on a substrate), and a step of developing the exposed substrate (processing the substrate with the pattern formed thereon). The manufacturing method also includes other known processes (oxidation, deposition, vapor deposition, doping, planarization, etching, resist removal, dicing, bonding, and packaging). The article manufacturing method according to this embodiment is advantageous in at least one of the performance, quality, productivity, and production cost of the article, as compared to conventional methods. Note that the above-described article manufacturing method may be performed using a lithography apparatus such as an imprint apparatus or a drawing apparatus.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2025-041570 filed on Mar. 14, 2025, which is hereby incorporated by reference herein in its entirety.

What is claimed is:

1. An actuator comprising a stator, and a mover configured to move along the stator, wherein
the mover comprises:
a housing;
a yoke;
a magnet adhered to one surface of the yoke via an adhesion layer; and
a plurality of fastening members configured to fasten the housing and the yoke, and
on an attachment surface of the housing, to which a structure of a driving target of the actuator is attached, the plurality of fastening members are arranged in a non-corner region other than corner regions including corner portions of a sectional region of a cross section of the yoke parallel to the attachment surface.

2. The actuator according to claim 1, wherein
the sectional region has a rectangular shape, and
the corner region is defined by a triangular region having one vertex at the corner portion of the sectional region.

3. The actuator according to claim 2, wherein
the plurality of fastening members are arranged along a plurality of rows in the non-corner region, and
the number of fastening members arranged on an outermost row in the plurality of rows is smaller than the number of fastening members arranged on a row inside the outermost row.

4. The actuator according to claim 3, wherein
the non-corner region includes an upper region, a lower region, and an intermediate region between the upper region and the lower region, which are defined along a moving direction of the mover,
the plurality of fastening members are arranged in the upper region and the lower region, and
in the intermediate region, the plurality of fastening members are not arranged, and the structure is attached.

5. The actuator according to claim 4, wherein
each of the upper region and the lower region is defined by a trapezoidal region having an opposite side of the one vertex as a leg, and
the intermediate region is defined by a rectangular region having, as opposite sides, a base of the trapezoid defining the upper region on the side of the intermediate region and a base of the trapezoid defining the lower region on the side of the intermediate region.

6. The actuator according to claim 2, wherein
the non-corner region is defined by an octagonal region including an opposite side of the one vertex, and
the plurality of fastening members are arranged along the octagon.

7. The actuator according to claim 2, wherein
the non-corner region is defined by an octagonal region including an opposite side of the one vertex, and
the plurality of fastening members are arranged along a rhombus inscribed with four sides except the opposite side of the one vertex among eight sides that define the octagon.

8. The actuator according to claim 2, wherein
the non-corner region is defined by an octagonal region including an opposite side of the one vertex, and
the plurality of fastening members are arranged along an ellipse inscribed with four sides except the opposite side of the one vertex among eight sides that define the octagon.

9. The actuator according to claim 1, wherein
the sectional region has a rectangular shape, and
the corner region is defined by a region surrounded by a first side and a second side, which define the corner portion of the sectional region, and a curve that connects one point on the first side and one point on the second side.

10. The actuator according to claim 9, wherein
the plurality of fastening members are arranged along the curve in the non-corner region.

11. The actuator according to claim 2, wherein
of two sides that define the one vertex of the triangle region, one side has a length not more than 10% a length of a long side of the sectional region, and the other side has a length not more than 10% a length of a short side of the sectional region.

12. The actuator according to claim 1, wherein
the plurality of fastening members include:
a first fastening member having a first stiffness; and
a second fastening member having a second stiffness lower than the first stiffness, and
the second fastening member is arranged at a position close to the corner region, as compared to the first fastening member.

13. The actuator according to claim 12, wherein
the first fastening member and the second fastening member are made of different materials.

14. The actuator according to claim 1, wherein
the plurality of fastening members include:
a first bolt having an underhead portion of a first diameter; and
a second bolt having an underhead portion including a portion of a second diameter smaller than the first diameter, and
the second bolt is arranged at a position close to the corner region, as compared to the first bolt.

15. The actuator according to claim 1, wherein
an axial stiffness of the plurality of fastening members is lower than a bending stiffness of the yoke.

16. The actuator according to claim 1, wherein
an arrangement of the plurality of fastening members on the attachment surface of the housing is different from the arrangement of the plurality of fastening members on other surfaces other than the attachment surface of the housing.

17. A stage apparatus comprising:
a stage; and
a driving unit including an actuator defined in claim 1 and configured to drive the stage,
wherein using the stage as a structure, the actuator applies a thrust to the stage.

18. A lithography apparatus for forming a pattern on a substrate, comprising:
a stage configured to hold the substrate; and
a driving unit including an actuator defined in claim 1 and configured to drive the stage,
wherein using the stage as a structure, the actuator applies a thrust to the stage.

19. The apparatus according to claim 18, further comprising a projection optical system configured to project a pattern of an original to the substrate.

20. An article manufacturing method comprising:
forming a pattern on a substrate using a lithography apparatus defined in claim 18;
processing the substrate on which the pattern is formed in the forming; and
manufacturing an article from the processed substrate.
